(19) United States
(12) Patent Application Publication
(10) Pub. No.: US 2023/0094481 A1
(43) Pub. Date: Mar. 30, 2023

(54) AMINO-SILANE COMPOUND AND COMPOSITION FOR THE SILICON-CONTAINING THIN FILM COMPRISING THE SAME

(71) Applicant: DUKSAN TECHOPIA CO., LTD., Cheonan-si, Chungcheongnam-do (KR)

(72) Inventors: Sang Woong YOON, Seoul (KR); Han Yong YANG, Seoul (KR); Hyoung Nam KIM, Jinju-si, Gyeongsangnam-do (KR); Gun Hyung JO, Daejeon (KR)

(73) Assignee: DUKSAN TECHOPIA CO., LTD., Cheonan-si, Chungcheongnam-do, OT (KR)

(21) Appl. No.: 16/976,494

(22) PCT Filed: Jul. 7, 2020
(86) PCT No.: PCT/KR2020/008857

§ 371 Date: Aug. 28, 2020

(51) Int. Cl. C07F 7/10; C23C 16/34; C23C 16/455

(52) U.S. Cl. CPC C07F 7/10; C23C 16/345; C23C 16/45553

(57) ABSTRACT

The present invention relates to an aminosilane compound and a composition for a silicon-containing thin film comprising the same, and more particularly, to an aminosilane compound and a composition for a silicon-containing thin film comprising the same having suitable properties that can be used as a precursor for forming a silicon-containing thin film and capable of replacing chlorosilanes.

### BACKGROUND

### Statement Regarding Government Support

This work was supported by the Korea Institute of Energy Technology Evaluation and Planning (KETEP) and the Ministry of Trade, Industry & Energy (MOTIE) of the Republic of Korea (No. 20172010106080).

### Technical Field

The present invention relates to an aminosilane compound and a composition for a silicon-containing thin film comprising the same, and more particularly, to an aminosilane compound and a composition for a silicon-containing thin film comprising the same having suitable properties that can be used as a precursor for forming a silicon-containing thin film and capable of replacing chlorosilanes.

### Background Art

Silicon-containing thin films are manufactured into various types of thin films such as silicon film, silicon oxide film, silicon nitride film, silicon carbonitride film, and silicon oxynitride film through various deposition processes in the semiconductor field and the applications of silicon-containing thin films are wide.

In particular, silicon oxide layer and silicon nitride layer act as an insulating layer, a diffusion barrier layer, a hard mask, an etching-stop layer, a seed layer, a spacer, a trench isolation layer, an intermetallic dielectric material, and a protective layer in device fabrication because they have very excellent blocking properties and oxidation resistance.

Silicon-containing thin films can be manufactured by various methods, for example, a chemical vapor deposition method (MOCVD) in which a mixed gaseous silicon precursor and a reactive gas react to form a film on the surface of the substrate or react directly on the surface to form a film, and atomic layer deposition (ALD) in which a gaseous silicon precursor is physically or chemically adsorbed on the surface of a substrate and then a film is formed by sequentially introducing a reactive gas. In addition, various thin film manufacturing technologies such as low-pressure chemical vapor deposition (LPCVD), and chemical vapor deposition (PECVD) and atomic layer deposition (PEALD) that can be deposited at low temperatures and using plasma are applied to the next-generation semiconductor and display device manufacturing processes, and are used to form ultra-fine patterns and deposit ultra-thin films having uniform and excellent properties in nano-scale thickness.

As disclosed in Korean Patent Publication No. 2007-0055898, a compound in the form of silane, silane chloride, aminosilane and alkoxysilane is typically used as the precursor to form the silicon-containing thin film, as a specific example, there are compounds in the form of silane chloride such as dichlororosilane(SiH₂Cl₂) and hexachlorodisilane(Cl₃SiSiCl₃), trisilylamine(N(SiH₃)₃), bis-diethylaminosilane (H₂Si(N(CH₂CH₃)₂)₂) and di-isopropylaminosilane(H₃SiN(i-C₃H₇)₂), etc. and the compound is used in semiconductor manufacturing and display manufacturing/mass production processes.

In order to form a good silicon-containing thin film, the precursor material must have a sufficiently high vapor pressure below 200° C. and must be thermally stable while being heated to be vaporized. In addition, the precursor material should also not only decompose rapidly at substrate temperature of 350-500° C. without decomposition of the organic material, but it should also have a low reactivity towards air and/or humidity during storage. Further, the precursor itself or the decomposed product of the precursor should not be toxic, and in view of economic efficiency, it is desirable that the precursor should be able to be manufactured simply and its raw material cost should be low.

[Prior Art]

1. Korean Patent Publication No. 10-2007-0055898 published on May 31, 2007

### Object, Technical Solution and Effects of the Invention

In one aspect, an object of the present invention is to provide a novel aminosilane compound having suitable properties that can be used as a precursor for forming a silicon-containing thin film and capable of replacing chlorosilanes.

In another aspect, an object of the present invention is to provide a composition for a silicon-containing thin film comprising a novel aminosilane compound according to one aspect of the present invention.

In one aspect of the present invention, the present invention provides an aminosilane compound represented by the following formula 1.

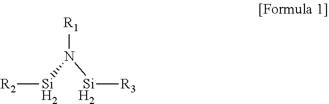

In another aspect of the present invention, the present invention provides a composition for depositing a silicon-containing thin film, wherein the composition comprises aminosilane compound represented by Formula 1.

The formation of a silicon-containing thin film using the aminosilane compound according to the present invention can be performed in a process state that does not require a separate catalyst, and by introducing a silazane-type aminosilane compound, the deposition rate and process efficiency can be excellent, compared to the conventional aminosilane precursor, and the aminosilane compound can also replace chlorosilanes.

### DETAILED DESCRIPTION

The novel aminosilane compound according to an embodiment of the present invention may be represented by the following Formula 1.

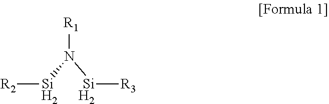

In Formula 1, each of symbols may be defined as follows.

R₁ may be selected from the group consisting of hydrogen, a C₁-C₂₀ alkyl group, a C₂-C₂₀ alkenyl group and a C₂-C₂₀ alkynyl group.

Preferably, R₁ may be a linear or branched saturated or unsaturated alkyl group, wherein an unsaturated alkyl group means an alkyl group containing at least one double bond or triple bond.

Where R₁ is an alkyl group, the alkyl group is, for example, a C₁-C₁₀, a C₁-C₉, a C₁-C₈, a C₁-C₇, a C₁-C₆, a C₁-C₅, a C₁-C₄, a C₁-C₃, a C₂-C₄, a C₃-C₄, a C₁, a C₂, a C₃, a C₄, a C₅, a C₆, a C₇, a C₈, a C₉, a C₁₀ alkyl group, specifically, methyl, ethyl, n-propyl, iso-propyl, n-butyl, t-butyl, sec-butyl, n-pentyl, iso-pentyl, neo-pentyl or sec-pentyl.

R₂ and R₃ may be each independently an amine group. Preferably, R₂ and R₃ may be each independently an amine group substituted with an alkyl group or aryl group, more preferably, may be each independently an amine group substituted with an alkyl group, and may be a primary or secondary amine group having a symmetrical or asymmetric structure.

Specifically, R₂ and R₃ may be each independently methyl amine, dimethyl amine, ethyl amine, diethyl amine, ethyl methyl amine, propyl amine, dipropyl amine, iso-propyl amine, diiso-propyl amine, n-butyl amine, dibutyl amine, t-butyl amine, di-tert-butyl amine, n-pentyl amine, dipentyl amine, iso-pentyl amine, diisopentyl amine, neo-pentyl amine, sec-pentyl amine and the like.

The alkyl group, the alkenyl group, the alkynyl group and the amine group may be each further substituted with one or more substituents selected from the group consisting of halogen, a cyano group, a nitro group, a C₁-C₂₀ alkyl group, a C₂-C₂₀ alkenyl group, a C₂-C₂₀ alkynyl group, a C₆-C₂₀ aryl group, a fluorenyl group, and a C₂-C₂₀ heterocyclic group containing at least one heteroatom selected from the group consisting of O, N, S, Si and P.

The compound represented by Formula 1 may be bis(ethylmethylamine)iso-propyl amino silazane(IPEM), bis(dimethylamine)t-butyl amino silazane(TBDM), or bis(ethylmethylamine)t-butyl amino silazane(TBEM).

The aminosilane compound according to one embodiment of the present invention represented by Formula 1 can be prepared using a non-polar solvent such as hexane, pentane, heptane, benzene and toluene, or a polar solvent diethyl ether, petroleum ether, tetrahydrofuran and 1,2-dimethoxy as a reaction solvent.

In another aspect of the present invention, the present invention provides a composition for depositing a silicon-containing thin film, wherein the silicon-containing thin film comprises the aminosilane compound represented by Formula 1.

Hereinafter, embodiments of the present invention will be described in more detail with reference to examples. These examples are for specifically explaining the present invention, and the scope of the present invention is not limited by the examples.

### EXAMPLE

### Example 1: Synthesis of bis(ethylmethylamine)iso-propyl amino silazane (IPEM)

Aminosilane compound according to Example 1 of the present invention can be prepared according to the following Reaction Schemes 1 and 2.

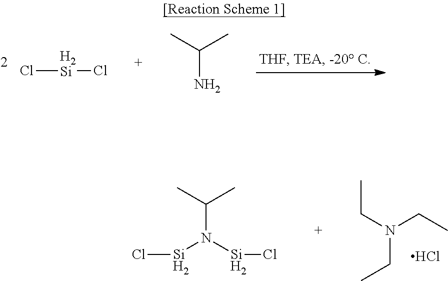

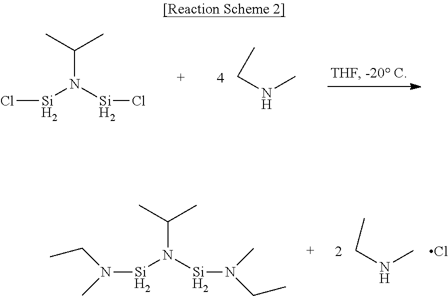

7,500 g of tetrahydrofuran (THF) was putted in a 20 L reactor and it cooled to −20° C. Thereafter, 500 g (2.0 eq) of dichlorosilane was added and 500 g (2 eq) of trimethylamine was added. Then, 146.3 g (1.0 eq) of isopropyl amine was added at the same temperature, the mixture was warmed to room temperature. After the reaction was performed for 16 hours, the reaction product was filtered and the filtrate was cooled to −20° C. Thereafter, 585.08 g (4.0 eq) of ethyl methyl amine was added to the filtrate, and the reaction was performed at room temperature for 16 hours. When the reaction was completed, the reaction product was filtered and the filtrate was concentrated under reduced pressure. When the solvent was removed, fractional distillation purification was performed to obtain 440.78 g of the compound.

Obtaining 440.78 g of colorless liquid, yield: 76.37%, purity: GC-FID 98.78%, MS m/z C₁₀H₂₉N₃Si₂ (M+) 233.51, found 231.9

¹H NMR (400 MHz, C₆D₆) δ 1.00 (t, 6H), δ 1.20(d, 6H), δ 2.48(s, 6H), δ 2.81-2.83 (q, 4H), δ 3.33-3.37(m, 1H) δ 4.82(s, 4H),

¹³C NMR (400 MHz, C₆D₆) δ 15.02, 26.05, 34.95, 45.65, 48.17

### Example 2: Synthesis of bis(dimethylamine)t-butyl amino silazane (TBDM)

Aminosilane compound according to Example 2 of the present invention can be prepared according to the following Reaction Schemes 3 and 4.

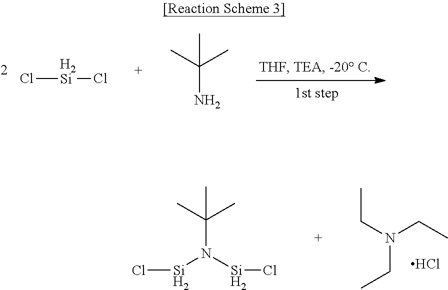

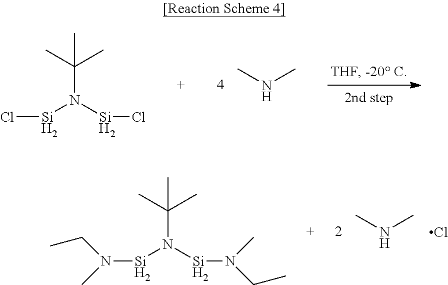

7,500 g of tetrahydrofuran (THF) was putted in a 20 L reactor and it cooled to −20° C. Thereafter, 500 g (2.0 eq) of dichlorosilane was added and 500 g (2 eq) of trimethylamine was added. Then, 181 g (1.0 eq) of t-butyl amine was added at the same temperature, and the mixture was warmed to room temperature. After the reaction was performed for 16 hours, the reaction product was filtered. The filtrate was cooled to −20° C. Thereafter, 446.21 g (4.0 eq) of dimethyl amine was added to the filtrate, and the reaction was performed at room temperature for 16 hours. When the reaction was completed, the reaction product was filtered and the filtrate was concentrated under reduced pressure. When the solvent was removed, fractional distillation purification was performed to obtain 380.79 g of the compound.

Obtaining 380.79 g of colorless liquid, yield: 70.1%, purity: GC-FID 98.3%, MS m/z C₁₀H₂₉N₃Si₂ (M+) 219.1, found 217.9

¹H NMR (400 MHz, C₆D₆) δ 1.30 (s, 9H), δ 2.46(s, 12H), δ 4.93(s, 4H)

¹³C NMR (400 MHz, C₆D₆) δ 14.13, 33.72, 33.98, 44.56, 52.15

### Example 3: Synthesis of bis(ethylmethylamine)t-butyl amino silazane (TBEM)

Aminosilane compound according to Example 3 of the present invention can be prepared according to the following Reaction Schemes 5 and 6.

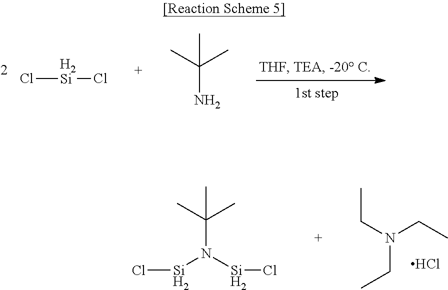

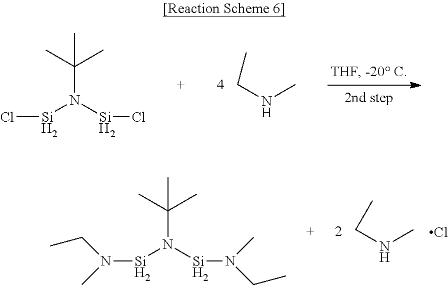

7,500 g of tetrahydrofuran (THF) was putted in a 20 L reactor and it cooled to −20° C. Thereafter, 500 g (2.0 eq) of dichlorosilane was added and 500 g (2 eq) of triethylamine was added. Then, 181 g (1.0 eq) of t-butyl amine was added at the same temperature, and the mixture was warmed to room temperature. After the reaction was performed for 16 hours, the reaction product was filtered. The filtrate was cooled to −20° C. Thereafter, 585.08 g (4.0 eq) of ethyl amine was added to the filtrate, and the reaction was performed at room temperature for 16 hours. When the reaction was completed, the reaction product was filtered and the filtrate was concentrated under reduced pressure. When the solvent was removed, fractional distillation purification was performed to obtain 435.65 g of the compound.

Obtaining 435.65 g of colorless liquid, yield: 71.21%, purity: GC-FID 98.3%, MS m/z C₁₀H₂₉N₃Si₂ (M+) 247.1, found 245.9

¹H NMR (400 MHz, C₆D₆) δ 0.99-1.02 (t, 6H), δ 1.34(s, 9H), δ 2.47(s, 6H), δ 2.80-2.85 (q, 4H), δ 4.97(s, 4H)

¹³C NMR (400 MHz, C₆D₆) δ 14.13, 32.72, 33.98, 44.56, 55.16

Although exemplary embodiments of the present invention have been described for illustrative purposes, those skilled in the art will appreciate that various modifications can be made without departing from the essential characteristics of the present invention. Therefore, the embodiments disclosed in the present invention are intended to illustrate the present invention, and the scope of the present invention is not limited by the embodiments. The scope of the present invention shall be construed on the basis of the accompanying claims, and it shall be construed that all of the technical ideas included within the scope equivalent to the claims belong to the present invention.

1. A aminosilane compound represented by Formula 1: 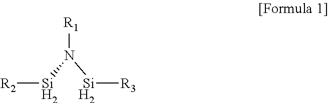
wherein:
R₁ is selected from the group consisting of hydrogen, a C₁-C₂₀ alkyl group, a C₂-C₂₀ alkenyl group and a C₂-C₂₀ alkynyl group,
R₂ and R₃ are each independently a primary or secondary amine group having a symmetrical or asymmetric structure, and
the alkyl group, the alkenyl group, the alkynyl group and the amine group may be each further substituted with one or more substituents selected from the group consisting of halogen, a cyano group, a nitro group, a C₁-C₂₀ alkyl group, a C₂-C₂₀ alkenyl group, a C₂-C₂₀ alkynyl group, a C₆-C₂₀ aryl group, a fluorenyl group, and a C₂-C₂₀ heterocyclic group containing at least one heteroatom selected from the group consisting of O, N, S, Si and P.

2. The compound of claim 1, wherein R₁ is an C₁-C₂₀ alkyl group, and R₂ and R₃ are a primary or secondary amine group substituted with an alkyl group.

3. The compound of claim 1, wherein R₁ is hydrogen, methyl, ethyl, n-propyl, iso-propyl, n-butyl, t-butyl, sec-butyl, n-pentyl, iso-pentyl, neo-pentyl, or sec-pentyl.

4. The compound of claim 1, wherein R₂ and R₃ are each independently methyl amine, dimethyl amine, ethyl amine, diethyl amine, ethyl methyl amine, propyl amine, dipropyl amine, iso-propyl amine, diiso-propyl amine, n-butyl amine, dibutyl amine, t-butyl amine, di-tert-butyl amine, n-pentyl amine, dipentyl amine, iso-pentyl amine, diisopentyl amine, neo-pentyl amine or sec-pentyl amine.

5. The compound of claim 1, wherein the aminosilane compound represented by Formula 1 is bis(ethylmethylamine)iso-propyl amino silazane (IPEM), bis(dimethylamine)t-butyl amino silazane (TBDM) or bis(ethylmethylamine)t-butyl amino silazane (TBEM).

6. A composition for depositing a silicon-containing thin film, wherein the silicon-containing thin film comprises the aminosilane compound of claim 1.
